(19) United States
(12) Patent Application Publication
(10) Pub. No.: US 2017/0196094 A1
(43) Pub. Date: Jul. 6, 2017

(54) ELECTRONIC COMPONENT PACKAGED IN A FLEXIBLE COMPONENT CARRIER

(71) Applicant: AT&S Austria, Leoben (AT)

(72) Inventor: Guenther MAYR, Milpitas, CA (US)

(21) Appl. No.: 14/984,011

(22) Filed: Dec. 30, 2015

(51) Int. Cl. H05K 1/18; H05K 1/03; H05K 1/11; H05K 1/02; H01L 23/00; H05K 3/32; H01L 23/538; H05K 1/09

(52) U.S. Cl. CPC H05K 1/185; H01L 23/5389; H05K 1/032; H05K 1/09; H05K 1/0298; H01L 24/83; H05K 3/32; H05K 1/115; H05K 2201/05; H01L 2224/838; H05K 2201/0141; H05K 2201/0154; H05K 2201/0162; H01L 2924/15153

(57) ABSTRACT

An electronic device comprising an electronic component with electric terminals, a component carrier in which the electronic component is packaged, wherein the component carrier comprises a flexible layer structure interposed between an upper rigid layer structure and a lower rigid layer structure, wherein the upper rigid layer structure comprises an upper cut-out portion and the lower rigid layer structure comprises a lower cut-out portion, and wherein the upper cut-out portion and the lower cut-out portion are formed at at least partially opposing positions relative to the flexible layer structure.

### FIELD OF THE INVENTION

Embodiments of the invention relate to an electronic device and a method of manufacturing an electronic device.

### Technological Background

Conventionally, naked dies and other electronic components are packaged in mold compounds made of plastic or resin. With continuous demand for small form factors and improved performance at lower costs, there is still room for improved packaging solutions.

The need for connectivity generally limits the degree of miniaturization that can be achieved. For small form factor devices, for example, the placement of a flex connector requires space and thus eats up real estate and causes a z-height (thickness) issue. Furthermore, the rigidity of packaged electronic devices often poses a problem during mounting within small spaces.

Accordingly, further adaptability and miniaturization is needed, in particular with regard to mounting and providing connectivity in such small devices as watches and interposers for socket testing.

There may be a need to enable compact packaging of electronic components which overcome the above-mentioned and other limitations.

### SUMMARY OF THE INVENTION

In order to achieve this need defined above, an electronic device and a method of manufacturing an electronic device according to the independent claims are provided.

According to an exemplary embodiment, an electronic device is provided which comprises an electronic component (such as a naked die) with electric terminals (for external electric connection of the electronic component), and a component carrier (i.e. a carrier structure in and/or on which one or more electronic components may be mounted) in which the electronic component is packaged or embedded, wherein the component carrier comprises (i.e. as part of the component carrier rather than as a separate member) a flexible layer structure interposed between an upper rigid layer structure and a lower rigid layer structure, wherein the upper rigid layer structure comprises an upper cut-out portion and the lower rigid layer structure comprises a lower cut-out portion, and wherein the upper cut-out portion and the lower cut-out portion are formed at at least partially opposing positions relative to the flexible layer structure (i.e. such that the respective cut-out portions are at least partially opposite to one another).

According to another exemplary embodiment, a method of manufacturing an electronic device is provided, wherein the method comprises (a) providing an electronic component (in particular a naked die) with electric terminals, (b) packaging or embedding the electronic component within a component carrier, wherein the component carrier comprises a flexible layer structure interposed between an upper rigid layer structure and a lower rigid layer structure, (c) forming an upper cut-out portion in the upper rigid layer structure, and (d) forming a lower cut-out portion in the lower rigid layer structure, wherein the upper cut-out portion and the lower cut-out portion are formed at at least partially opposing positions relative to the flexible layer structure.

In the context of the present application, the term “component carrier” may particularly denote any support structure which is capable of accommodating one or more electronic components thereon and/or therein for providing both mechanical support and electrical connectivity.

In the context of the present application, the term “cut-out portion” may particularly denote a region where material has been removed or cut-out, e.g. by laser cutting, drilling or similar methods.

In the context of the present application, the indication that “the upper cut-out portion and the lower cut-out portion are formed at at least partially opposing positions” denotes that the upper cut-out portion is at least partially overlapping the lower cut-out portion. In other words, either a part of the upper cut-out portion is overlapping (i.e. opposite to) (at least) a part of the lower cut-out portion or the entire upper cut-out portion is overlapping the lower cut-out portion.

According to an exemplary embodiment, an electronic device having at least one electronic component packaged or embedded in a component carrier is provided, wherein at least one flexible region is formed by at least partially opposing cut-out portions in upper and lower rigid layer structures of the component carrier. In the area corresponding to the opposing cut-out portions no (or only little) rigid material is present, such that the flexible characteristics of the thus (more or less) exposed flexible layer structure dominate. The remaining part of the component carrier is as rigid as the upper and lower rigid layer structures. In other words, the component carrier comprises the flexible layer structure as a flexible core in a stack or sandwich-like structure with the upper and lower rigid layer structures containing corresponding cut-out portions at selected positions where flexibility is desired. In sum, a mainly rigid compact electronic device with at least one flexible region is provided.

In the following, further exemplary embodiments of the electronic device and the method will be explained.

In an embodiment, the flexible layer structure comprises a first layer structure of flexible material selected from the group consisting of polyimide, FR4 material, R-FR10 material, silicone elastomer based material, in particular silicone, and liquid crystal polymer. In particular polyimide provides excellent flexibility, in particular in terms of bending. A thin layer of FR4 material may also provide good flexibility. R-FR10 material denotes a polyimide core to which a copper coating is adhered. The latter may be used to form a conductive structure.

In an embodiment, the flexible layer structure comprises a second layer structure of electrically conductive material selected from the group consisting of copper, aluminum, and nickel. The second layer structure may be used to provide electrical connections between the rigid parts of the component carrier. One rigid part of the component carrier may for example have the electronic component embedded therein, while another rigid part of the component carrier may be equipped with a connector for providing electric connections between the embedded electronic component and an external device or another part of the device. In this case, the rigid part containing the connector may be moved relative to the rigid part containing the embedded electronic component, e.g. by bending the flexible layer structure exposed by the upper and lower cut-out portions.

In an embodiment, the flexible layer structure comprises an electrically insulating coating at least on surface parts corresponding to the upper cut-out portion and the lower cut-out portion. The electrically insulating coating protects conductive structures on the flexible layer and prevents short circuits or damage.

In an embodiment, the upper cut-out portion and the lower cut-out portion have substantially identical shapes. Thereby, a well-defined flexible region is provided which allows the rigid parts of the component carrier to be bent to similar extents in both directions (i.e. up and down).

In an embodiment, the upper cut-out portion and the lower cut-out portion have rectangular shapes. A rectangular flexible region is advantageous as it allows bending along an elongate axis, i.e. the longer dimension of the rectangular shape. Thus, a rigid part of the component carrier may easily be flipped relative to another rigid part of the component carrier. However, it should be noted that the cut-out portions may have other shapes than rectangular, such as triangular or other polygonal shapes as well as combinations of two or more (possibly different) polygonal shapes.

In an embodiment, the upper rigid layer structure comprises a further upper cut-out portion and the lower rigid layer structure comprises a further lower cut-out portion, and the further upper cut-out portion and the further lower cut-out portion are formed at at least partially opposing positions relative to the flexible layer structure. The further cut-out portions provide a further flexible region in the same manner as described above. By having more flexible regions, more individually moveable or adjustable parts (e.g. containing flex connectors) are provided. For example, the component carrier may have one flexible region to the left of a central part containing the embedded electronic component and a further flexible region to the left of said central part, thereby providing individually flipable or tiltable left and right side regions or wings. In a similar manner, front and rear flexible regions may be added to obtain a total of four flexible wings surrounding the central part of the component carrier. If the geometry and/or size of the component carrier allow it, even further (i.e. more than four) flexible regions may be added.

In an embodiment, the electronic component is arranged in a cut-out portion in the flexible layer structure. In other words, in this embodiment the electronic component is mounted in a suitably formed cut-out portion in the flexible layer structure, which thus has a thickness sufficient to accommodate the electronic component which (together with the flexible layer structure) is surrounded by the upper and lower rigid layer structures.

In an embodiment, the upper and/or lower rigid layer structure comprises a layer of material selected from the group consisting of prepreg material and resin coated copper. The upper and/or lower rigid layer structures may comprise several layers of material, in particular also including electrically conductive layers.

In an embodiment, the electronic component is a naked die, in particular an unpackaged semiconductor chip. In such an embodiment, the electronic device may be kept very small, since the naked die can be packaged within the component carrier without requiring a molding compound (or the like) surrounding it, for instance made of plastic or resin. Thus, the electronic device architecture not only provides at least one flexible region, but also a compact packaging technology within a component carrier.

In an embodiment, the flexible layer structure, the upper rigid layer structure and the lower rigid layer structure of the component carrier form (i.e. comprise or consist of) a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure, if desired supported by thermal energy. The mentioned stack may provide a plate-shaped component carrier capable of providing a large mounting surface for further electronic components and being nevertheless very thin and compact. The term “layer structure” may particularly denote a continuous layer, a patterned layer or a plurality of non-consecutive islands within a common plane.

In an embodiment, the at least one electrically insulating layer structure comprises at least one of the group consisting of resin, in particular Bismaleimide-Triazine resin, cyanate ester, glass, in particular glass fibers, prepreg material, polyimide, liquid crystal polymer, epoxy-based Build-Up Film, FR4 material, silicone elastomer based material, in particular silicone, a ceramic, and a metal oxide. Although prepreg or FR4 are usually preferred, other materials may be used as well.

In an embodiment, the at least one electrically conductive layer strucLure comprises at least one of the group consisting of copper, aluminum, and nickel. Although copper is usually preferred, other materials are possible as well.

In an embodiment, the component carrier is shaped as a plate. This contributes to the compact design of the electronic device, wherein the component carrier nevertheless provides a large basis for mounting electronic components thereon. Furthermore, in particular a naked die as preferred example for an embedded electronic component, can be conveniently embedded, thanks to its small thickness, into a thin plate such as a printed circuit board.

In an embodiment, the component carrier is configured as one of the group consisting of a printed circuit board, and a substrate.

In the context of the present application, the term “printed circuit board” (PCB) may particularly denote a plate-shaped component carrier which is formed by laminating several electrically conductive layer structures with several electrically insulating layer structures, for instance by applying pressure, if desired accompanied by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming through-holes through the laminate, for instance by laser drilling or mechanical drilling, and by filling them with electrically conductive material (in particular copper), thereby forming vias as through-hole connections. Apart from one or more electronic components which may be embedded in a printed circuit board, a printed circuit board is usually configured for accommodating one or more electronic components on one or both opposing surfaces of the plate-shaped printed circuit board. They may be connected to the respective main surface by soldering.

In the context of the present application, the term “substrate” may particularly denote a small component carrier having substantially the same size as an electronic component to be mounted thereon.

In an embodiment, the electronic component is selected from a group consisting of an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, a sensor, an actuator, a microelectromechanical system, a microprocessor, a capacitor, a resistor, an inductance, a battery, a switch, a camera, an antenna, a magnetic element, and a logic chip. However, other electronic components may be embedded in the electronic device. For example, a magnetic element can be used as an electronic component. Such a magnetic element may be a permanent magnetic element (such as a ferromagnetic element, an antiferromagnetic element or a ferrimagnetic element, for instance a ferrite core) or may be a paramagnetic element. Such an electronic component may be surfacemounted on the component carrier and/or may be embedded in an interior thereof.

In an embodiment, the component carrier is a laminate-type component carrier. In such an embodiment, the component carrier is a compound of multiple layer structures which are stacked and connected together by applying a pressing force, if desired accompanied by heat.

In an embodiment, the method step of packaging the electronic component within the component carrier comprises (a) providing a layer of flexible material, in particular polyimide, silicone elastomer based material like silicone or liquid crystal polymer, (b) forming a cut-out portion in the layer of flexible material, (c) arranging the electronic component in the formed cut-out portion, and (d) forming the upper rigid layer structure and the lower rigid layer structure on an upper respectively lower side of the flexible layer structure.

In an embodiment, the method further comprises applying an adhesive material to thereby adhere the electronic component vertically between the upper and lower rigid layer structures and laterally to the flexible layer structure. By adhering the electronic component to the upper and lower rigid layer structures and to the flexible layer structure, proper positioning and fastening of the embedded electronic component can be obtained.

In an embodiment, the method further comprises forming terminal contacting blind holes through at least one of the upper and lower rigid layer structures and the adhesive material to thereby expose the electric terminals. By taking this measure, a simple and reliable external contacting of the electric terminals of the embedded electronic component is accomplished.

The aspects defined above and further aspects of embodiments of the invention are apparent from the examples of embodiment to be described hereinafter and are explained with reference to these examples of embodiment.

### DETAILED DESCRIPTION OF THE DRAWINGS

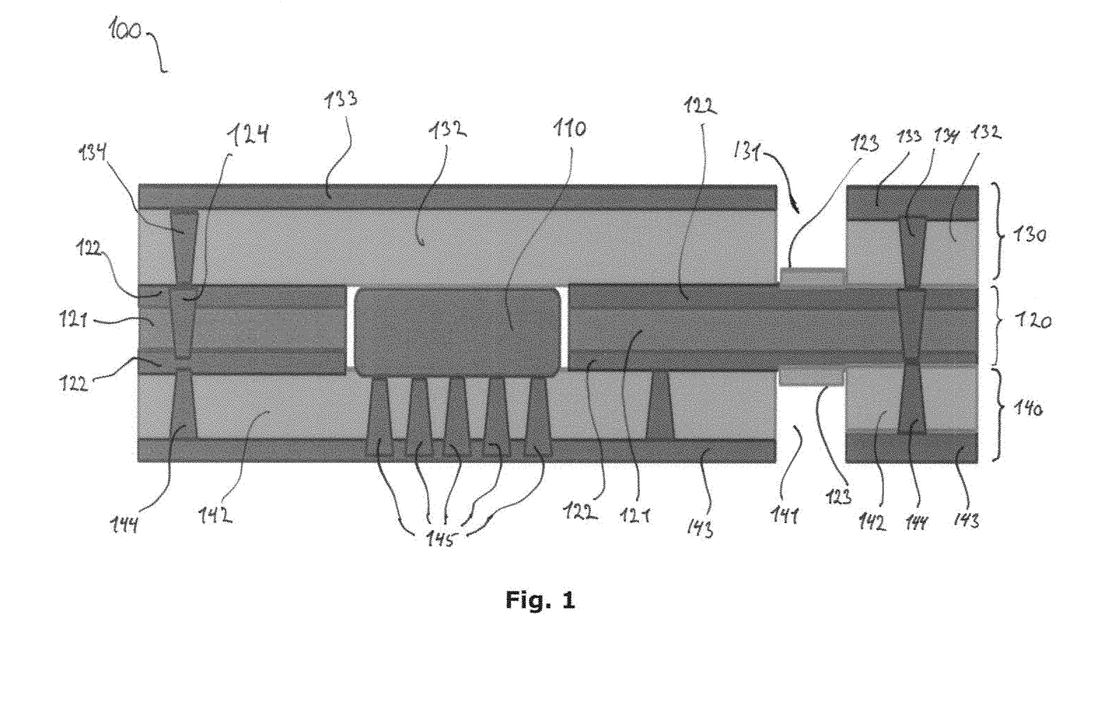

FIG. 1 shows a cross-sectional view of an electronic device according to an exemplary embodiment of the invention.

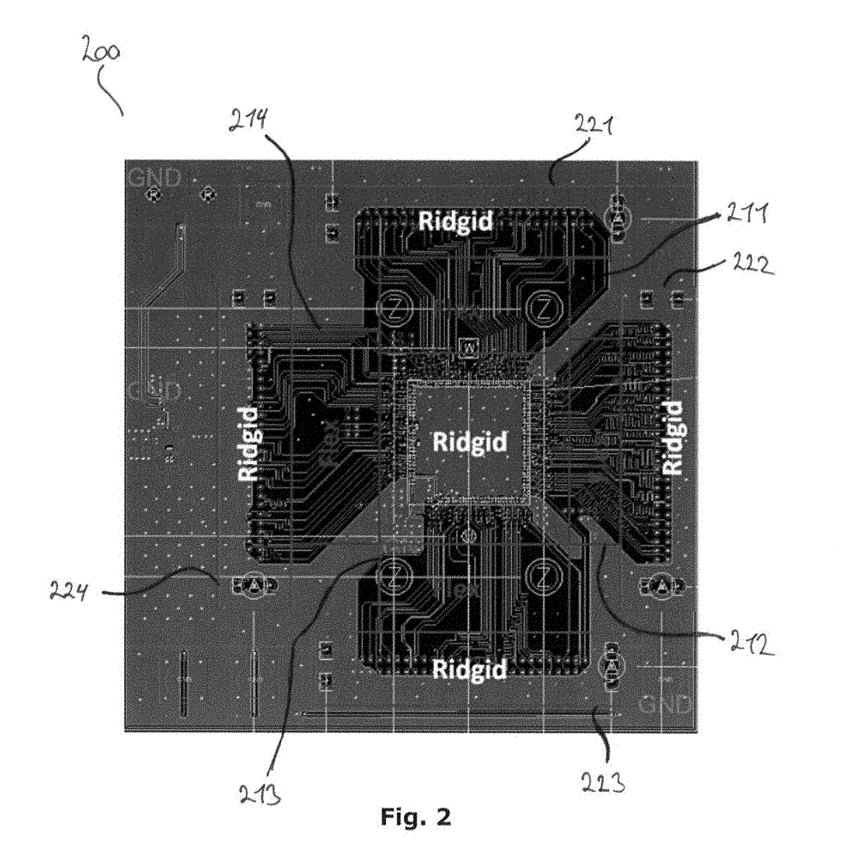

FIG. 2 shows a top view of an electronic device according to an exemplary embodiment of the invention.

The illustrations in the drawings are schematic. In different drawings, similar or identical elements are provided with the same reference signs.

### DETAILED DESCRIPTION OF EXEMPLARY EMBODIMENTS

FIG. 1 shows a cross-sectional view of an electronic device 100 according to an exemplary embodiment of the invention. More specifically, the electronic device 100 comprises an electronic component 110 which is packaged in a component carrier comprising a flexible layer structure 120, an upper rigid layer structure 130 and a lower rigid layer structure 140.

The flexible layer structure 120 comprises a flexible layer 121, e.g. a polyimide layer, covered by layers 122 of conductive material, e.g. copper, on both sides, i.e. the upper and lower sides. The electronic component 110 is arranged in a cut-out portion or cavity in the flexible layer structure 120 and adhered to the respective side walls of the cavity.

The upper rigid layer structure 130 is formed on the upper side of the flexible layer structure 120 and the lower rigid layer structure 140 is formed on the lower side of the flexible layer structure 120. Thereby, the flexible layer structure 120 is interposed between the upper and lower rigid layer structures 130 and 140. The upper rigid layer structure 130 comprises a layer 132 of rigid material, such as a prepreg or resin coated copper (RCC) material, and a conductive layer structure 133. Furthermore, a cut-out portion 131 is formed (e.g. by laser cutting) in the upper rigid layer structure 130. Similarly, the lower rigid layer structure 140 comprises a layer 142 of rigid material, such as a prepreg or resin coated copper (RCC) material, and a conductive layer structure 143. Furthermore, a cut-out portion 141 is formed (e.g. by laser cutting) in the lower rigid layer structure 140. The cut-out portions 131 and 141 are positioned opposite to one another and extend through the upper and lower rigid layer structures 130 and 140, respectively, such that the interposed flexible layer structure 120 is exposed through the cut-out portions 131 and 141. The exposed surface parts of the flexible layer structure are covered by a protective layer 123, such as a protective film or coating. In the present exemplary embodiment, the cut-out portions 131 and 141 are shown as completely overlapping each other. However, in other exemplary embodiments, the cut-out portions may only partially overlap each other in the sense that the upper cut-out portion 131 may be displaced slightly to the left or right (relative to the drawing) and/or the lower cut-out portion 141 may be displaced slightly to the right or left.

The upper conductive layer structure 133 of the upper rigid layer structure 130 is interconnected with the upper conductive layer structure 122 of the flexible layer structure 120 by vias 134 filled with conductive material, e.g. copper. Similarly, the lower conductive layer structure 143 of the lower rigid layer structure 140 is interconnected with the lower conductive layer structure 122 of the flexible layer structure 120 by vias 144 filled with conductive material. The upper and lower conductive layer structures 122 of the flexible layer structure 120 are interconnected by vias 124 filled with conductive material. The terminals (not shown) of the electronic component 110 are connected to the lower conductive layer structure 143 of the lower rigid layer structure 140 by vias 145 filled with conductive material. Thereby, a complete conductive structure is formed. It is explicitly noted although the terminals of electronic component 110 in the exemplary embodiment shown in FIG. 1 are only connected to the lower conductive layer structure 143 (through vias 145), similar connections to the upper conductive layer structure 133 may be provided in other exemplary embodiments where the electronic component comprises terminals on both its upper and lower side.

As a result of the opposing cut-out portions 131 and 141, the electronic device 100 will have the flexible properties of the flexible layer structure 120 in a region corresponding to the cut-out portions 131 and 141 and be rigid in the remaining parts of the device. Accordingly, due to the exposed flexible layer structure 120 in the opposing cut-out portions 131 and 141, the part of the electronic device 100 on either side of the cut-out portions 131, 141 may be flipped up or down relative to part of the electronic device 100 on the other side of the cut-out portions 131, 141 by bending the exposed part of the flexible layer structure 120. This may e.g. be useful when connecting a flex connector (not shown) of the electronic device to a corresponding connector or cable as well as in cases where some flexibility is needed to mount the electronic device 100, e.g. in a watch.

The electronic device 100 may e.g. be manufactured by providing the flexible layer structure 120, for example as a flexible layer 121 of polyimide or FR4 material covered with electrically conductive material, such as copper, for forming an electrically conductive layer structure 122 on one or both sides, e.g. by a lithography process. Then a part of the material of the flexible layer structure 120 is removed, e.g. by laser cutting, where the electronic component 110 is to be arranged. The electronic component 110 may be arranged in the cut-out portion of the flexible layer structure 120 by placing it on a sticky tape, applying a pick and place procedure and gluing it to the side walls of the flexible layer structure 120 within the cut-out portion. Then, the upper rigid layer structure 130 and lower rigid layer structure 140 are laminated onto the flexible layer structure 120. In this regard, the cut-out portions 131 may be formed prior to the lamination or afterwards, e.g. by cutting. For example, pre-cut prepreg and laminate incl. soldermask coating and patterning (including 2.5D release layer print material in areas needed for cavity processing) may be placed and further processed through hot press lamination. For alignment methods, skiving technology may be used to achieve a well aligned core to the following press step. Once this 4-layer core is being finished, standard HDI processing will be used to achieve the final layer count (8, 10, 12 or more layers, for example). Once the final layer count is met, the laser cutting or if needed depth routing from the front and back side is used to create a cavity. Contact routing improves z-height tolerances and is a valid option to meet alignment needs. The above described process can also be applied for applications where the polyimide laminate is replaced with standard FR4 laminates (50-70/μm thick). If more than 2-layers are needed in the flex region (where the cut-out portions 131 and 141 are located) for routing purposes, the polyimide laminate 121 can be pressed with one RCC on each side to increase to 4-layer and to achieve at least one (if needed two) shielding or ground layer for signal integrity performance. Laser vias 124, 134, 144, 145 can be distributed throughout the circuit board (electronic device).

FIG. 2 shows a top view of an electronic device 200 according to an exemplary embodiment of the invention. More specifically, the electronic device 200 is a laminated circuit board with at least one embedded electronic component (not shown) and layered structures corresponding to those discussed above in conjunction with the electronic device 100 of FIG. 1.

The electronic device 200 comprises four pairs of cut-out portions, each essentially corresponding to the pair cut-out portions 131, 141 in FIG. 1. The corresponding flexible regions are indicated by reference numerals 211, 212, 213 and 214 in FIG. 2 and allow displacement of the corresponding rigid portions (or flex tails) 221, 222, 223 and 224, e.g. by flipping the latter out of the plane of the drawing. The central area surrounded by the four flexible regions 211, 212, 213 and 214 is also a region portion, where the one or more electronic components are preferably located.

As can be seen from the above description of exemplary embodiments, there are provided flexible and compact electronic devices which are suitable for numerous applications where small form factors and flexibility are important.

It should be noted that the term “comprising” does not exclude other elements or steps and the “a” or “an” does not exclude a plurality. Also elements described in association with different embodiments may be combined.

It should also be noted that reference signs in the claims shall not be construed as limiting the scope of the claims.

Implementation of the invention is not limited to the preferred embodiments shown in the figures and described above. Instead, a multiplicity of variants is possible which use the solutions shown and the principle according to the invention even in the case of fundamentally different embodiments.

What is claimed is:

1. An electronic device, the electronic device comprising:
an electronic component with electric terminals;
a component carrier in which the electronic component is packaged;
wherein the component carrier comprises a flexible layer structure interposed between an upper rigid layer structure and a lower rigid layer structure, wherein the upper rigid layer structure comprises an upper cut-out portion and the lower rigid layer structure comprises a lower cut-out portion, and wherein the upper cut-out portion and the lower cut-out portion are formed at at least partially opposing positions relative to the flexible layer structure.

2. The electronic device according to claim 1, wherein the flexible layer structure comprises a first layer structure of flexible material selected from the group consisting of polyimide, FR4 material, R-FR10 material, silicone elastomer based material, in particular silicone, and liquid crystal polymer.

3. The electronic device according to claim 2, wherein the flexible layer structure comprises a second layer structure of electrically conductive material selected from the group consisting of copper, aluminum, and nickel.

4. The electronic device according to claim 1, wherein the flexible layer structure comprises an electrically insulating coating at least on surface parts corresponding to the upper cut-out portion and the lower cut-out portion.

5. The electronic device according to claim 1, wherein the upper cut-out portion and the lower cut-out portion have substantially identical shapes.

6. The electronic device according to claim 1, wherein the upper cut-out portion and the lower cut-out portion have rectangular shapes.

7. The electronic device according to claim 1, wherein the upper rigid layer structure comprises a further upper cut-out portion and the lower rigid layer structure comprises a further lower cut-out portion, and wherein the further upper cut-out portion and the further lower cut-out portion are formed at at least partially opposing positions relative to the flexible layer structure.

8. The electronic device according to claim 1, wherein the electronic component is arranged in a cut-out portion in the flexible layer structure.

9. The electronic device according to claim 1, wherein the upper and/or lower rigid layer structure comprises a layer of material selected from the group consisting of prepreg material and resin coated copper.

10. The electronic device according to claim 1, wherein the electronic component is a naked die, in particular an unpackaged semiconductor chip.

11. The electronic device according to claim 1, wherein the flexible layer structure, the upper rigid layer structure and the lower rigid layer structure of the component carrier form a stack of at least one electrically insulating layer structure and at least one electrically conductive layer structure.

12. The electronic device according to claim 11, wherein the at least one electrically insulating layer structure comprises at least one of the group consisting of resin, in particular Bismaleimide-Triazine resin, cyanate ester, glass, in particular glass fibers, prepreg material, polyimide, liquid crystal polymer, epoxy-based Build-Up Film, FR4 material, silicone elastomer based material, in particular silicone, a ceramic, and a metal oxide.

13. The electronic device according to claim 11, wherein the at least one electrically conductive layer structure comprises at least one of the group consisting of copper, aluminum, and nickel.

14. The electronic device according to claim 1, wherein the component carrier is shaped as a plate.

15. The electronic device to claim 1, wherein the component carrier is configured as one of the group consisting of a printed circuit board, and a substrate.

16. The electronic device according to claim 1, wherein the electronic component is selected from a group consisting of an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, a sensor, an actuator, a microelectromechanical system, a microprocessor, a capacitor, a resistor, an inductance, a battery, a switch, a camera, an antenna, a magnetic element, and a logic chip.

17. The electronic device according to claim 1, wherein the component carrier is a laminate-type component carrier.

18. A method of manufacturing an electronic device, the method comprising:
providing an electronic component, in particular a naked die, with electric terminals;
packaging the electronic component within a component carrier, wherein the component carrier comprises a flexible layer structure interposed between an upper rigid layer structure and a lower rigid layer structure;
forming an upper cut-out portion in the upper rigid layer structure; and
forming a lower cut-out portion in the lower rigid layer structure, wherein the upper cut-out portion and the lower cut-out portion are formed at at least partially opposing positions relative to the flexible layer structure.

19. The method according to claim 18, wherein packaging the electronic component within the component carrier comprises
providing a layer of flexible material, in particular polyimide, silicone elastomer based material like silicone or liquid crystal polymer;
forming a cut-out portion in the layer of flexible material;
arranging the electronic component in the formed cut-out portion; and
forming the upper rigid layer structure and the lower rigid layer structure on an upper respectively lower side of the flexible layer structure.

20. The method according to claim 18, further comprising applying an adhesive material to thereby adhere the electronic component vertically between the upper and lower rigid layer structures and laterally to the flexible layer structure.

21. The method according to claim 20, further comprising forming terminal contacting blind holes through at least one of the upper and lower rigid layer structures and the adhesive material to thereby expose at least a part of the electric terminals of the electronic component.
